(19) United States
(12) Patent Application Publication
(10) Pub. No.: US 2005/0269699 A1
(43) Pub. Date: Dec. 8, 2005

(54) Ball grid array solder joint reliability

(76) Inventors: Tan Tzyy Haw, Penang (MY); Toh Teik Sean, Kedah (MY); Ho Swee Cheng, Butterworth (MY)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/200,884

(22) Filed: Aug. 9, 2005

Related U.S. Application Data
(62) Division of application No. 10/609,203, filed on Jun. 26, 2003.

(51) Int. Cl. H01L 23/52

(52) U.S. Cl. 257/737; 257/738; 257/698; 257/692

(57) ABSTRACT

An apparatus and system are provided for improving ball grid array (BGA) joint reliability. According to one embodiment, a ball grid array (BGA) package having a first and second surface and an array of solder balls to align the first surface with the second surface is disclosed. The first surface is coupled to an integrated circuit (IC) device and the second surface is coupled to a printed circuit board (PCB). A bonder is applied between the first surface and second surface independently of the array of solder balls.

### RELATED APPLICATION

This application is a divisional application of U.S. application Ser. No. 10/609,203, filed on Jun. 26, 2003, and priority is claimed thereof.

### BACKGROUND OF THE INVENTION

1. Field of the Invention

The invention generally relates to ball grid array (BGA) device assembly, and more particularly to improving BGA joint reliability.

2. Description of the Related Art

As many integrated circuit (IC) devices are getting faster, smaller, and thinner with changing electronic devices, particularly in terms of size and functionality, ball grid array (BGA) solder joint reliability to the printed circuit board (PCB) is becoming an increasing concern. BGA package refers to a type of common surface mount chip package including a printed circuit board (PCB) using solder balls (or solder bumps) to electronically connect an IC device to the PCB, instead of using a lead frame. However, difficulties, due to, for example, board flex ness caused by mechanical stress and temperature change during the board assembly process, in surface mount soldering of the IC device with the PCB and keeping the BGA package structure in tact are well-known.

Typically, a BGA package includes a grid of solder balls as its joints to connect the IC device with the PCB. Typically, a BGA chip package includes aligning the BGA with the printed circuit board (PCB) using the BGA solder balls. Solder paste as solder joint may be applied to each of the solder balls, the IC device surface, and the PCB surface to create the physical contact and solder the BGA package. Typically, the IC device is connected with a PCB, both electronically and mechanically, by heating the assembly until the solder balls flow to connect to terminals provided on the PCB. During this process, board flex ness caused by thermal expansion from heat processes stressing the solder joints may be the primary concern of the BGA assembly process, as the flexed board may be severed with excessive external stress applied on it. Nevertheless, the conventional BGA packages solely rely on solder joints for attachment of the IC device with the PCB and for stability of the BGA package structure.

Many attempts have been made to improve BGA joint reliability and to minimize additional stretch to the BGA solder balls to avoid BGA opening and cracking. Most of the changes have been made on the process and assembly side; for example, processes, such as solder reflow, solder wave, profile optimization, and assembly and testing are reformed to provide a better handling process of the BGA package. However, none of the methods, apparatus, and systems available today provides any increase in the joint strength of the BGA packages.

Furthermore, although several attempts have been made to optimize the process profile to reduce the stretch “feel” on the BGA solder joints, such attempts, nevertheless, fail due to thermal expansion and mechanical stress during the assembly process and also due to additional stretch caused by follow up processes. Some of the follow up processes include board flex ness during handling, in-circuit, and functional testing in the board factory environment, manual testing in the system assembly, and even handling at the customer end. The stretch normally results in loss of parallelism between the BGA package and the PCB surface by, for example, excessive external mechanical stress.

FIG. 1a illustrates a cross-sectional view of a conventional prior art ball grid array package having a convex warpage. As illustrated, the warping of the BGA package 100 occurs at the edges of the BGA package 100, as the area near the edges is typically the weakest area. The lack of strength and support in the conventional solder joints 110, 112 may result in the weakening of the solder joints 110, 112 at the edges. Such weakening of the solder joints 110, 112 may cause the solder balls 106, 108 at the edges to, first, stretch vertically and, then, detach from the solder joints 110, 112 due to, for example, convex outward bending of the PCB (bottom surface) 104. The outward bending of the bottom surface 104 results in the BGA package 100 losing its ideal parallel structure.

FIG. 1b illustrates a cross-sectional view of a conventional prior art ball grid array package having a concave warpage. As illustrated, the lack of strength and support in the conventional solder joints, such as solder joints 110, 112, may result in the excessive compression of the solder joints 110, 112 at the edges caused by, for example, the bottom surface 104 to bending inwards and turning concave. Such compression of the solder joints 110, 112 may cause the solder balls 106, 108 at the edges to stretch horizontally, creating, for example, electrical short between the solder balls 106 to 107, 108 to 109.

None of the methods, apparatus, and systems available today provide enough strength and support to the BGA package to withhold stretch applied to the solder balls due to board flex ness caused by excessive external mechanical stress and thermal expansion during various processes. The lack of strength and support provided by the conventional solder joints results in the stretching of the solder balls, and warping and deformation of the PCB surface and the BGA package. The warping results in the PCB surface to bend and the BGA package to lose its intended and ideal parallel structure.

### BRIEF DESCRIPTION OF THE DRAWINGS

The appended claims set forth the features of the present invention with particularity. The embodiments of the present invention, together with its advantages, may be best understood from the following detailed description taken in conjunction with the accompanying drawings of which:

FIG. 1a illustrates a cross-sectional view of a prior art ball grid array package having a convex warpage;

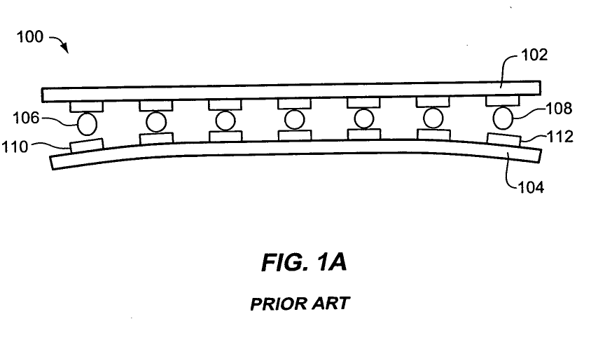

FIG. 1b illustrates a cross-sectional view of a prior art ball grid array package having a concave warpage;

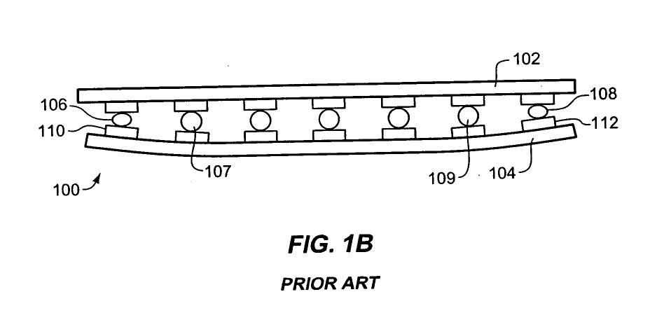

FIG. 2 illustrates the cross-sectional view of a typical ball array grid package;

FIG. 3 illustrates an embodiment of the cross-sectional view of a typical ball array grid package;

FIG. 4 illustrates an embodiment of the top view of a ball array grid package;

FIG. 5a illustrates an embodiment of the cross-sectional view of a ball grid array package;

FIG. 5b illustrates an embodiment of the top view of a ball grid array package;

FIG. 6 is a flow chart illustrating an embodiment of a process of using a thermoplastic bonder with a ball array grid package; and

FIG. 7 is a flow chart illustrating an embodiment of a process of using a silicon bonder with a ball array grid package.

### DETAILED DESCRIPTION

An apparatus and system are described for integrated circuit (IC) device and printed circuit board (PCB) integration and packaging. Broadly stated, embodiments of the present invention provide for improving ball grid array (BGA) joint reliability.

A system, apparatus, and method are provided for increasing the reliability of BGA packages under mechanical stress and temperature variations. According to one embodiment, a bonder may be applied to an area of weakness of a BGA package to provide additional strength and support between the PCB surface and the BGA package. The bonder, according to one embodiment, may be include thermoplastic material or silicon material or the like, and may be discretely applied to the PCB surface and the BGA package. Typically, the area including edges, corners, and perimeter of the BGA package are determined to be the weakest area.

A BGA package may include a top surface electrically and mechanically connected with an IC device, and a bottom surface electrically and mechanically connected with a printed circuit board (PCB). The bottom surface may also be known as the PCB surface. The BGA package may further include an array of alignment solder balls to align the top surface with the bottom surface. Typically, solder paste or solder joints may be applied between the solder balls and the top surface, as well as between the solder balls and the bottom surface. According to one embodiment, a bonder may be applied to, for example, the PCB surface and the BGA package between the top surface and the bottom surface independent of the solder balls and the solder joints to provide support to the BGA package and maintain its parallel structure. The application of the bonder may provide resistance to mechanical stress and thermal expansion during assembly and other subsequent processes.

The embodiments of the present invention include various steps, which will be described below. The steps may be performed manually or using various hardware components or may be embodied in machine-executable instructions, which may be used to cause a processor or machine or logic circuits programmed with the instructions to perform the steps. Furthermore, the steps may be performed manually and/or automatically.

In the following description, for the purposes of explanation, numerous specific details are set forth in order to provide a thorough understanding of the present invention. It will be apparent, however, to one skilled in the art, based on the disclosure provided herein, that the embodiments of the present invention might be practiced without some of these specific details. For example, structural, logical, and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. In other instances, well-known structures and devices are shown in block diagram form.

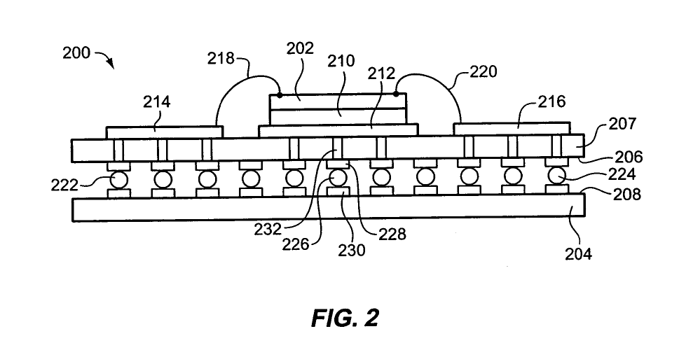

FIG. 2 illustrates a cross-sectional view of a typical ball array grid package. As illustrated, the ball grid array (BGA) package 200 includes an integrated circuit or semiconductor device or silicon chip (chip) 202 packaged (or coupled) with a printed circuit board (PCB) 204. The chip 202 may be coupled with a die pad 212 using an adhesive material 210. The die pad 212 may rest on a board 207, such as a laminated board, having an insulation layer (top surface) 206. Additional layers or surfaces or boards may be included and placed or stacked upon each other.

The BGA package 200 may include additional pattern layers 214, 216 placed on the laminated board 207. The pattern layers 214, 216 may be electronically connected with the top of the chip 202 using wires, such as gold wires 218, 220. The BGA package 200 may include a grid of solder balls, such as solder balls 222-226, as its joints to connect the chip 202 with the PCB 204. Stated differently, the top surface 202 of the BGA package 200 may be aligned with the PCB surface (bottom surface) 208 using an array of solder balls 222-226. Solder balls 222-226 are also known as solder interconnection balls or solder bumps. As illustrated, the solder balls 222-226 may be placed in a selected pattern, such as in rows and columns, between the top surface 206 and the bottom surface 208. Solder balls 222-226 may be used to transmit electrical signals between the chip 202 and the PCB 204. The solder balls 222-226 may serve as ground or power source contacts. Furthermore, solder balls 222-226 may be used to dissipate heat away from the chip 202 by, for example, transferring the heat to the various heat dissipating points on the PCB 204.

Typically, solder paste may be applied to each of the solder balls, such as 222-226 of the BGA package 200. For example, the solder paste may be applied between the top surface 206 and each of the solder balls, such as solder ball 226, as well as between the bottom surface 208 and each of the solder balls, such as solder ball 226, providing the physical contact between the chip 202 and the PCB 204. Solder paste may then be transformed into solder joints, such as the solder joints 228, 230, during one of the processes. The solder joints 228, 230, like solder balls 222-226, may be used to transmit electrical signals between the chip 202 and the PCB 204. Solder joints 228, 230 may also provide connection between the PCB 204 and the chip 202 via their connection with contacts in the PCB 204, and with the chip 202 by vias, such as 232.

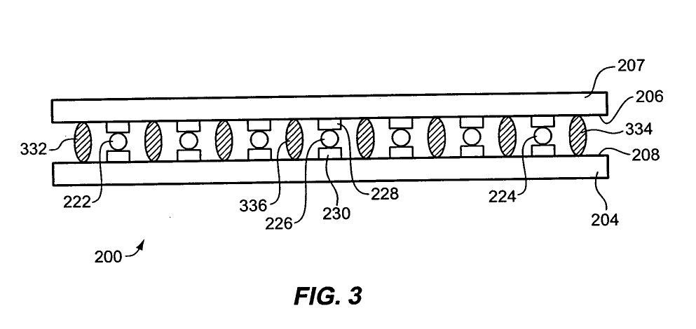

FIG. 3 illustrates an embodiment of a cross-sectional view of a ball array grid package. As illustrated in FIG. 2, according to one embodiment, the ball grid array (BGA) package 200 may include an integrated circuit (IC) or semiconductor device or silicon chip (chip), not illustrated, packaged with a printed circuit board (PCB) 204.

According to one embodiment, as illustrated, the BGA package 200 may include an insulation layer 207 having a surface (top surface) 206, and the PCB 204 having a surface (bottom surface) 208. The top surface 206 may be aligned with the bottom surface 208 using a grid of solder balls, such as 222-226, also known as solder interconnection balls or solder bumps.

Typically, solder balls, such as 222-226, may be used to transmit electrical signals between the chip and the PCB 204. The solder balls 222-226 may serve as ground or power source contacts. Furthermore, the solder balls 222-226 may be used to dissipate heat away from the chip by, for example, transferring the heat to the various heat dissipating points on the PCB 204. To provide strength and support to the BGA package 200, solder paste may be applied to each of the solder balls, such as solder balls 222-226, of the BGA package 200. To use the solder ball 226 as an example, solder paste may be applied between the solder ball 226 and the top surface 206 as well as between the solder ball 226 and the bottom surface 208. Solder paste may then be transformed into solder joints, such as 228, 230 during various processes.

According to one embodiment, a bonder, such as 332-336, may be applied to the BGA package 200 to provide strength and support to the BGA package 200. Typically, the BGA package 200 may be intended and designed to maintain a parallel structure. Stated differently, ideally, the top surface 206 and bottom surface 208 may be placed to stay in a parallel formation with respect to each other. Although, the solder joints 228, 230 may be used to provide some strength to the BGA package 200, the strength provided by the solder joints 228, 230 is not enough to withstand, for example, mechanical stress, thermal expansion, and temperature variances. For example, during the reflow process, the temperature may rise up to 205-225degree Celsius, and during the wave process, the solder pot temperature may rise up to 240+/−1% degree Celsius, while typical solder joints 228, 230 may have a melting temperature of 183 degree Celsius. Some of the characteristics of the reflow process are as follows: reflow temperature may be in the range of 205-225 degree Celsius, soak time (or pre-heat time) may in the range of 60-120 seconds, and time to reach 183 degree Celsius may be in the range of 40-90 seconds. Some of the characteristics of the wave process are as follows: solder pot temperature may be 240+/−1% degree Celsius, primary side temperature may be less than 160 degree Celsius, and the dwell time may be in the range of 1.3-3.3 seconds or 2.3-4.3 seconds depending of the PCB thickness.

According to one embodiment, to provide strength and support to the BGA package 200 and to maintain its parallel structure, even during mechanical stress and thermal expansion, a bonder 332-336 may be introduced to the BGA package 200. The BGA package 200, according to one embodiment, may already have an array of solder joints, such as 228, 230; and, according to another embodiment, may not have the solder joints 228, 230. The bonder 332-336, according to one embodiment, may be a thermoplastic material-based bonder or a silicone material-based bonder, or the like. The bonder 332-336 may be used to increase the solder joint reliability providing additional strength and support and parallelism between top surface 206 and the bottom surface 208 of the BGA package 200 to resist and tolerate stress and stretch caused by, for example, high-density BGA packages 200, mechanical stress, thermal expansion, and temperature variations.

Typically, the edges, corners, and perimeters (edges) of the BGA package 200 may include the weakest areas where the cracking and opening of the solder joints is most expected. Some of the BGA packages may not even have a full array of solder balls, such as 222-226, causing the edges to be even weaker. Stated differently, some of the BGA packages 200 may have most solder balls within the central area where the chip is likely to be located, leaving the edges susceptible to warpage. According to one embodiment, the bonder, such as 332-336, may be applied to the edges of the BGA package 200 before or after the assembly process depending on one or more factors, such as the material of the bonder 332-336. According to another embodiment, the bonder 332-336 may be applied to the edges of the BGA package 200 during the assembly process depending on one or more factors, such as the bonder material. The bonder 332-336 may also be applied to other areas of the BGA package 200 for various reasons, such as to provide additional strength, or as necessitated. Applying the bonder 332-336 to the edges may not only help support the weakest areas of the BGA package 200, but also applying the bonder 332-336 to the edges may be relatively easy.

According to one embodiment, the bonder 332-336 may be applied as paste forming the shape of balls in between the top surface and the bottom surface of the BGA package. According to one embodiment, the bonder 332-336 may be applied before, after, or during the assembly process to reduce the BGA solder balls 222-226 from stretching and to prevent the BGA solder joints 228, 230 from cracking or opening, which may be caused by additional stretch induced during the assembly process and subsequent processes.

According to one embodiment, the bonder 332-336 may include thermoplastic material, or silicon material, or the like. Both the thermoplastic bonder and the silicon bonder may increase the strength of the solder joints 228, 230 between the top surface 206 and the bottom surface 208; however, other advantages, such as cost, application timing, and bonding force, of using the bonder 332-336 may depend on whether the bonder 332-336 includes thermoplastic or silicon or some other material. For example, by using thermoplastic material, the bonder 332-336 may add up to 800 psi bonding force to the BGA package 200; however, by using silicon material, the additional force may be up to 1000 psi.

According to one embodiment, the process of attaching or applying the bonder 332-336 may be different if thermoplastic material is used as opposed to silicon material or some other material due to the differences in the characteristics of the various materials. For example, the melting temperature for thermoplastic material (under 120 degree Celsius) is lower than that of silicone material (above 250 degree Celsius) and thus, the thermoplastic bonder may be applied later during the process (e.g. after the processes of solder reflow and solder wave) than if the silicon bonder was being used which may be applied prior to the solder reflow and wave processes. Furthermore, the process of attaching or applying the bonder 332-336 may also vary from manufacturer to manufacturer.

According to one embodiment, the chip, such as chip 202 of FIG. 2, may include any computational or processing circuit, such as a microprocessor, a microcontroller, a graphics processor, a digital signal processor (DSP), a complex instruction set computing (CISC) processor, a reduced instruction set computing (RISC) processor, or a very long instruction word (VLIW) processor. The chip 202 may be part of a computer system or physical machine, such as a mainframe computer, a handheld device, a workstation, a server, a portable computer, a set-top box, an intelligent apparatus or system or appliance, a virtual machine, or any other computing system or device.

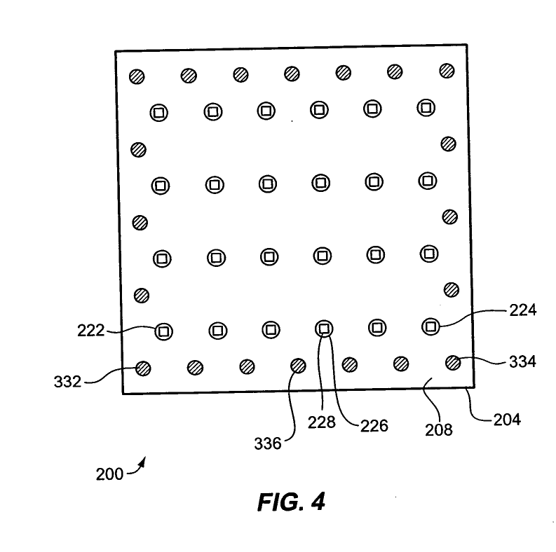

FIG. 4 illustrates an embodiment of a top view of a ball array grid package. According to one embodiment, the ball grid array (BGA) package 200 may include an integrated circuit or semiconductor device or silicon chip (chip), not illustrated, attached with a printed circuit board (PCB) 204 using an array of solder balls. According to one embodiment, the insulation layer surface (top surface), not illustrated, may be aligned with the PCB surface (bottom surface) 208 of the PCB 204 using solder balls, such as solder balls 222-226, and solder joints, such as solder joint 228. Solder joints 228 may be placed between the solder balls 222-226 and the top surface and bottom surface 208 in a variety of forms, such as in rows and columns, as illustrated.

Typically, the edges, corner or perimeter (edges) of the BGA package 200 are regarded as the weakest areas susceptible to cracking, opening, and warpage. According to one embodiment, a bonder, such as bonder 332-336, may be applied between the top surface and the bottom surface 208 of the BGA package 200 to provide additional strength and support to resist and tolerate, for example, thermal expansion during various processes, such as assembly, and/or mechanical stress during handling, and testing. To provide maximum strength and support without using too much bonder 332-336, the bonder 332-336 may be applied at the edges of the BGA package 200, as illustrated. Applying the bonder 332-336 to the edges of the BGA package may help prevent the concave and convex bending of the bottom surface 208 when the solder balls 222-226 are stretched due to, for example, thermal expansion and external mechanical stress. According to another embodiment, the bonder 332-336 may also be applied to the center of the BGA package 200 for various reasons, such as to provide additional strength to the BGA package 200 or for the bonder 332-336 to be directly the chip, since the chip typically is placed in the middle of the BGA package 200. According to one embodiment, the bonder 332-336 may include thermoplastic material, silicon material, or the like.

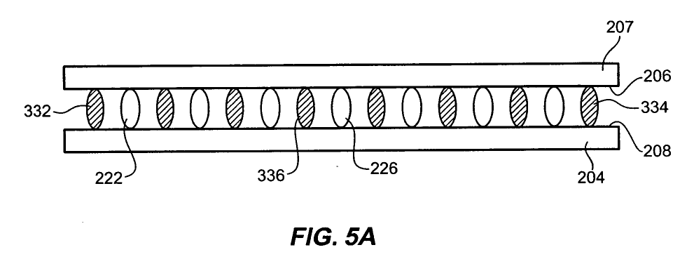

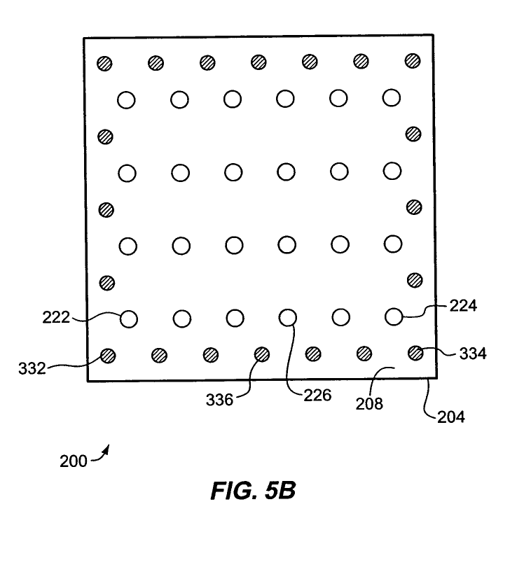

FIG. 5a illustrates an embodiment of a cross-sectional view of a ball grid array package. According to one embodiment, the bonder, such as bonder 332-336 as detailed in FIGS. 3 and 4, may be applied to the ball grid array (BGA) package 200 without the solder joints, such as the solder joints 228, 230 of FIGS. 2-4. According to one embodiment, the bonder 332-336 may be applied as a substitute for the solder joints. Stated differently, according to one embodiment, the solder joints that are typically included in a BGA package 200 may not be necessary. According to one embodiment, only the bonder, such as bonder 332-336, may be sufficient to provide the necessary strength and support to the BGA package 200 to resist and tolerate any mechanical stress, temperature variations, and thermal expansion to avoid warpage of the BGA package 200, including convex and concave bending of the printed circuit board (PCB) 204 and the PCB surface (bottom surface) 208.

As illustrated, the BGA package 200 may include a top surface 206 aligned with the bottom surface 208 using an array of solder balls, such as the solder balls 222-226. According to one embodiment, at the edges, corners, or perimeter of the BGA package 200, the bonder 332-336 may be applied to provide sufficient strength and support to the BGA package to prevent warpage. According to another embodiment, the bonder 332-336 may be applied at other areas of the BGA package 200.

FIG. 5b illustrates an embodiment of a top view of a ball grid array package. As with FIG. 5a, according to one embodiment, only the bonder, such as the bonder 332-336, may be sufficient to provide the necessary strength and support to the BGA package 200 to avoid warpage of the BGA package 200, including convex and concave bending of the printed circuit board (PCB) 204 and the PCB surface (bottom surface) 208. Stated differently, the bonder, such as bonder 332-336 as detailed in FIGS. 3 and 4, may be applied to the ball grid array (BGA) package 200 without the solder joints, such as solder joints 228, 230 of FIGS. 2-4, or the bonder 332-336 may be applied as a substitute for the solder joints.

According to one embodiment, the BGA package 200 includes a PCB 204 and the bottom surface 208. As illustrated, the BGA package 200 may further include an array of solder balls, such as the solder balls 222-226 without the solder joints, such as the solder joints 228, 230 of FIGS. 2-4. The BGA package 200 also includes a bonder, such as the bonder 332-336, at the edges, corners, or perimeter to provide additional strength and support to prevent warpage or deformation.

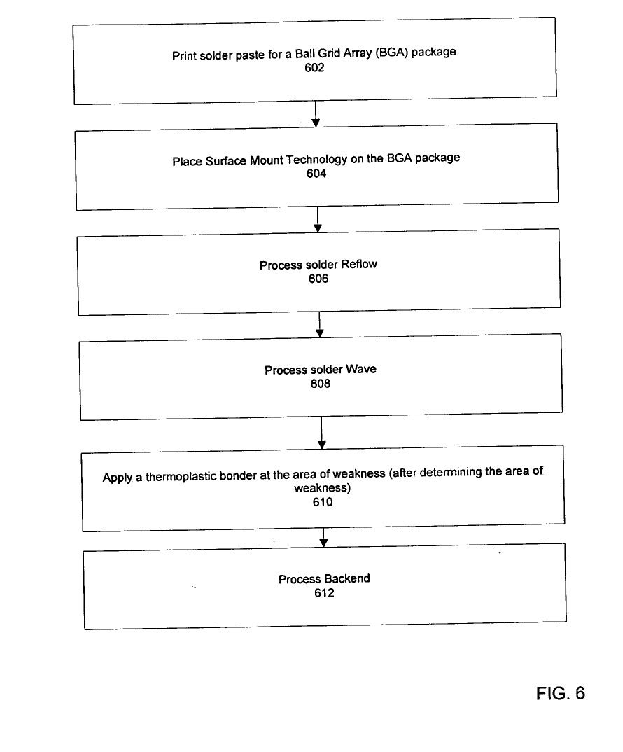

FIG. 6 is a flow chart illustrating an embodiment of a process of using a thermoplastic bonder with a ball array grid package. At processing block 602, solder plate may be printed to be applied to the ball grid array (BGA) package. Typically, solder pate, which is later transformed into solder joints, may be applied to certain areas of the insulation layer (top surface) and the printed circuit board (PCB) surface (bottom surface) with solder balls in between the solder paste on each surface. Solder paste or solder joints may act as adhesive to temporarily hold the BGA package in place. A typical BGA package employs a surface mount technology (SMT). SMT includes surface mount soldering of various devices and circuits. For example, the packaging of integrated circuits or semiconductor devices or silicon chips (chip) and PCB using a BGA package is well known.

At processing block 604, SMT may be applied using solder balls and solder joints. SMT component may be applied to the BGA package, e.g., to the bottom surface, using a placement machine. Solder balls may allow SMT devices to have wider tolerance range with regard to the flatness surfaces, such as the top surface and bottom surface of the BGA package. Solder paste may be applied between each of the solder balls and the top surface, and between each of the solder balls and the bottom surface. Solder balls may provide more solder per joint on the top and bottom surfaces than can typically be supplied with only solder joints. According to one embodiment, the solder joints may not be necessary and may not be included in the BGA package. A BGA package, according to one embodiment, may include an array of solder balls, e.g. rows and columns of solder balls, to provide electrical connection and mechanical bond to the BGA package. Furthermore, for example, using SMT in BGA packages, solder balls may be used to cover the area as large as one and a half (1½) inch square.

According to one embodiment, at processing block 606, solder reflow is performed. Solder reflow may include one or more of the following: pre-heat zone, soak zone, reflow zone, and cooling zone. The pre-heat zone may include initial heating of, e.g., the lead component, followed by the soak zone. The soak zone may be to bring the temperature of the BGA package up to a uniform temperature to minimize temperature gradients. Furthermore, the soak zone may include the dry out and solder paste activities involving the evaporation of most of the solder paste and chemical activation of the flux in the solder paste. The soak zone may be followed by the reflow zone, which may include keeping the temperature above melting point of solder joints for about 40-90 seconds. The peak temperature may be high enough for some flux action and wetting. The final stage of the reflow process may include the cooling zone which may include gradual cooling to prevent any thermal shock to the chip, and attempting to produce a lower fatigue resistance of solder joints.

At processing block 608, solder wave is performed. The wave process may include one or more of the following: fluxing, pre-heat, chip-flux, and lambda wave. Fluxing may include applying of liquid to the base of, for example, the bottom surface and plating the barrel of holes through the through hole component. Pre-heat may include rising of the temperature of the BGA package to speed up the soldering operation and to minimize exposure to the solder wave. Pre-heat may further include activation of flux chemistry and evaporation of volatiles in the flux. The chip-flux process may include improving the soldering performance on surface mount design before the lambda-wave process. The lambda wave process may include having the solder flow in one direction against the travel of the BGA package, and the solder may also flow backwards with the BGA package when it is contact with solder wave.

Typically, as the processes of solder reflow and solder wave are performed, the flow of solder may cause thermal expansion along with mechanical stress on the BGA packages including a change in the shape of the solder balls and the solder joints. According to one embodiment, a thermoplastic material-based bonder may be applied to the BGA package to provide the necessary strength and support to the BGA package and help maintain its parallel structure at processing block 610. According to one embodiment, the thermoplastic bonder may be applied after the processes of solder reflow and solder wave to provide additional strength and support to the weaker solder balls and the BGA package to accommodate tolerance variation.

According to one embodiment, the thermoplastic bonder may be dispensed (or applied) using a bonder dispenser used for dispensing the bonder of any material. According to another embodiment, a specialized thermoplastic bonder dispenser may be used for dispensing of the thermoplastic bonder. Furthermore, one or more bonder dispensers may be used for dispensing of the thermoplastic bonder. According to one embodiment, the thermoplastic bonder may be applied in its solid form to the edges of the BGA package after the process of solder wave. The solid form of the thermoplastic bonder may be applied using a hot melting jig or a dispenser. According to one embodiment, the hot melting jig or the dispenser may include one or more of the following: Asymtek Dispenser System, hot melt hand applicator, ITW Dynamelt, and Adhesive Unit. According to one embodiment, software or a software application may be used to control the placement distance of the thermoplastic bonder with respect to the solder balls or the array of solder balls, so that the thermoplastic bonder may be applied independent of the solder balls. According to another embodiment, the placement of the thermoplastic bonder may be performed using other mechanisms not involving software, or a combination of software and other non-software mechanisms.

According to one embodiment, the area of weakness of the BGA package may be determined prior to applying the bonder so that the bonder may be applied to the weakest area of the BGA package to provide maximum strength and support using the minimum amount of the bonder. Typically, the corners, edges, and perimeter (edges) are determined to be the weakest areas of BGA package. According to one embodiment, a thermoplastic bonder may be applied between the top surface and the bottom surface of the BGA package. According to one embodiment, the thermoplastic bonder may be applied independently of the solder balls and solder joints, e.g., without touching any of the solder balls or solder joints. According to one embodiment, the BGA package may not include any solder joints, and only the thermoplastic bonder may be sufficient to provide the necessary strength and support, and the thermoplastic bonder may still be applied independently of the solder balls.

With regard to using the thermoplastic bonder, according to one embodiment, since the melting temperature of thermoplastic material may be lower than the temperature of, for example, solder reflow and solder wave, the thermoplastic bonder may be applied after the processes of solder reflow and solder wave. The application of the thermoplastic bonder may provide the necessary strength and support to the BGA package to withstand thermal expansion and mechanical stress and to maintain the parallel structure of the BGA package. According to another embodiment, the thermoplastic bonder or a bonder including another material, such as silicon, may be applied before or during certain processes, such as solder reflow and solder wave, if the melting temperature of the bonder used is higher than the certain processes mentioned above.

At processing block 612, the backend process may be performed. The backend process may include a board assembly testing and inspection processes depending on the BGA package assembly. For example, the backend process may include one or more of the following: post-wave inspection, incircuit test, functional test, final inspection, outgoing quality assurance test, and outgoing quality check. The post-wave inspection may include an operator performing the secondary side inspection of the BGA package to, for example, ensure that the solder ability meets factory specification. The incircuit test may include performing testing with various equipment, such as Agilent 3070, Teradyne, and TR8001, with either vacuum suction or push down fixture. During the process, the defects due to previous processes, such as the SMT placement, solder reflow, and solder may be filtered out. Functional test may be performed to ensure the quality of the BGA package functionality to the customers. Furthermore, the functional test may be performed using functional tester, which may be either a pneumatic fixture or mechanical assist fixture. Final inspection may be performed by an operator to inspect the chip, the soldering, and other components of the BGA package by using various templates. Outgoing quality assurance test may include simulating the customer environment to ensure the BGA package quality at the customer end. Finally, the outgoing quality check may include inspecting all items and components to further ensure the quality of the BGA package. The items and components may include serial numbers, product label, customized labels, etc.

According to one embodiment, the thermoplastic bonder may be applied to provide additional strength and support to BGA packages to maintain their parallel structure between the top surface and the bottom surface of BGA package. The application of the thermoplastic bonder to BGA packages may provide the BGA packages with additional tolerance and resistance to thermal expansion and mechanical stress, and may help prevent the solder balls from stretching and deforming.

According to one embodiment, some of the characteristics of thermoplastic material used in a thermoplastic bonder may include the following: melting temperature of 120 degree Celsius (or less), the thermoplastic bonder may be recyclable after use and may stay solid after it is cured, the force required to break the solder joints when using a thermoplastic bonder may be in the range of 200-300 psi with a maximum force of up to 800 psi, an adhesive may be used to apply the thermoplastic bonder to the BGA package, and the thermoplastic bonder may be economical in cost as compared to a silicon bonder. Furthermore, the curing time for the thermoplastic bonder may be faster than that of the silicon bonder, for example, in the ratio of 1:5. Thermoplastic material may be available from various manufacturers, such as 3M Corporation.

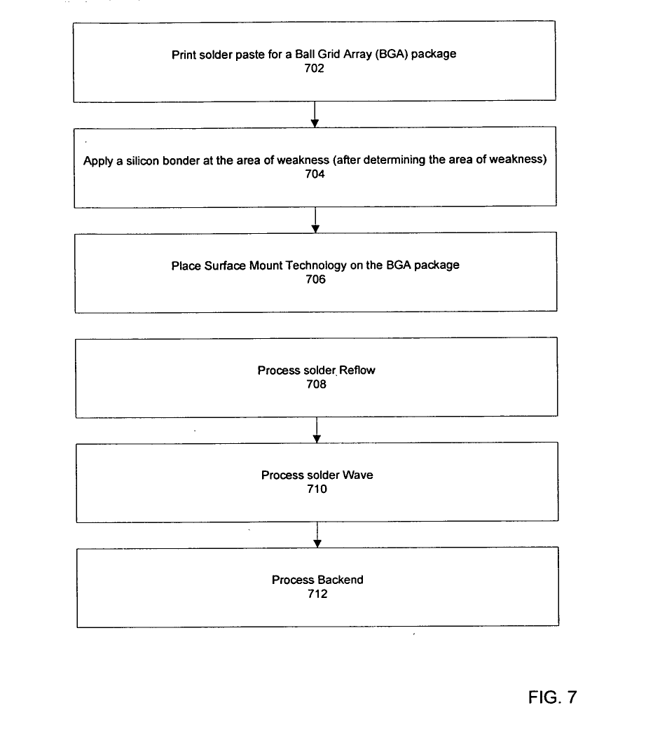

FIG. 7 is a flow chart illustrating an embodiment of a process of using a silicon bonder with a ball array grid package. At processing block 702, solder paste may be printed to be applied to a ball grid array (BGA) package. Typically, solder pate, which is later transformed into solder joints, may be applied to certain areas of the insulation layer (top surface) and the printed circuit board (PCB) surface (bottom surface) with solder balls in between the solder paste on each surface. Solder paste or solder joints may act as adhesive to temporarily hold the BGA package in place. A typical BGA package employs a surface mount technology (SMT). SMT includes surface mount soldering of various devices and circuits. For example, the packaging of integrated circuits or semiconductor devices or silicon chips (chip) and PCB using a BGA package is well known.

According to one embodiment, a silicon material-based bonder may be applied to the BGA package to provide strength and support to the solder balls to accommodate tolerance variations due to, for example, thermal expansion and mechanical stress at processing block 704. According to one embodiment, a silicon bonder may be applied between the top surface and the bottom surface of the BGA package independent of or separate from the solder balls and solder joints. According to one embodiment, the silicon bonder may be dispensed (or applied) using a bonder dispenser used for dispensing the bonder of any material. According to another embodiment, a specialized silicon bonder dispenser may be used for dispensing of the silicon bonder. Furthermore, one or more bonder dispensers may be used for dispensing of the silicon bonder. According to one embodiment, the silicon bonder may be applied to the edges of the BGA package before the BGA package placement. According to one embodiment, the application of the silicon bonder may be performed using an epoxy dispenser machine with silicon volume, and placement distance control through software. Stated differently, according to one embodiment, the silicon bonder may be dispensed using an epoxy dispenser machine, and, for example, software or a software application may be used to control the placement distance of the silicon bonder with respect to the solder balls or the array of solder balls, so that the silicon bonder may be applied independent of the solder balls. According to another embodiment, the placement of the silicon bonder may be performed using other mechanisms not involving software, or a combination of software and other non-software mechanisms.

According to one embodiment, the area of weakness of the BGA package may be determined prior to applying the bonder so that the bonder may be applied to the weakest area of the BGA package to provide maximum strength and support using the minimum amount of the bonder. Typically, the corners, edges, and perimeter (edges) are determined to be the weakest areas of the BGA package.

At processing block 706, SMT may be applied using solder balls and solder joints. SMT component may be applied to the BGA package, e.g., to the bottom surface, using a placement machine. According to one embodiment, solder balls may allow SMT devices to have wider tolerance range with regard to the flatness surfaces, such as the top surface and the bottom surface of the BGA package. Solder paste, which is later transformed into solder joints, may be applied between each of the solder balls and the top surface, and between each of the solder balls and the bottom surface. According to one embodiment, the joints may not be necessary and thus, may not be included in the BGA package.

According to one embodiment, at processing block 708, solder reflow may be performed. Solder reflow may include one or more of the following: pre-heat zone, soak zone, reflow zone, and cooling zone, as described in reference to FIG. 6. At processing block 710, solder wave may be performed. The wave process may include one or more of the following: fluxing, pre-heat, chip-flux, and lambda wave, as described in reference to FIG. 6.

According to one embodiment, a silicon bonder may be applied between the top surface and the bottom surface of the BGA package. According to one embodiment, the silicon bonder may be applied independently of the solder balls and solder joints, e.g., without directly touching or contacting any of the solder balls or solder joints. According to one embodiment, the BGA package may not include any solder joints, and only the silicon bonder may be sufficient to provide the necessary strength and support to the BGA package.

With regard to using the silicon bonder, according to one embodiment, since the melting temperature of silicon material may be greater than the temperature of, for example, solder reflow and solder wave, the silicon bonder may be applied before the processes of solder reflow and solder wave. According to another embodiment, the silicon bonder or a bonder made of another material, such as thermoplastic material, may be applied after the processes of, for example, solder reflow and solder wave, if necessitated or if the melting temperature of the bonder used is lower than that of the processes mentioned above.

At processing block 712, the backend process may be performed. The backend process may include a board assembly testing and inspection processes depending on the BGA package assembly. For example, the backend process may include one or more of the following: post-wave inspection, incircuit test, functional test, final inspection, outgoing quality assurance test, and outgoing quality check, as described in reference to FIG. 6.

According to one embodiment, some of the characteristics of silicon material used in a silicon bonder may include the following: melting temperature of 250 degree Celsius (or above); the silicon bonder may not be recyclable after use and may be rubbery after it is cured; the force required to break the solder joints when using a silicon bonder may be in the range of 200-300 psi with a maximum force of up to 1000 psi, an adhesive may be used to apply the silicon bonder to the BGA package, and the silicon bonder may be more expensive in cost when compared to the thermoplastic bonder. Furthermore, the curing time for the silicon bonder may be slower than that of the thermoplastic bonder, for example, in the ratio of 5:1. Silicon material may be available from various manufacturers, such as Dow Corning Corporation.

While certain exemplary embodiments of the invention have been described and shown in the accompanying drawings, it is to be understood that such embodiments are merely illustrative of and not restrictive on the broad aspects of various embodiments of the invention, and that these embodiments not be limited to the specific constructions and arrangements shown and described, since various other modifications are possible. It is possible to implement the embodiments of the invention or some of their features in hardware, programmable devices, firmware, software, or a combination thereof.

1. An apparatus, comprising:
a ball grid array (BGA) package having a first surface, a second surface and an array of solder balls to align the first surface with the second surface, the first surface coupled with an integrated circuit (IC) device and the second surface coupled with a printed circuit board (PCB); and
a bonder applied between the first surface and the second surface independently of the array of solder balls.

2. The apparatus of claim 1, further comprising solder joints to attach the array of solder balls with the first surface and the second surface.

3. The apparatus of claim 1, wherein the bonder comprises a thermoplastic bonder, the thermoplastic bonder is applied using a hot melting jig or a dispenser, the hot melting jig and the dispenser comprise at least one of a hot melt hand applicator, and an adhesive unit.

4. The apparatus of claim 1, wherein the bonder comprises a silicon bonder, the silicon bonder is applied using an epoxy dispenser machine with silicon volume.

5. The apparatus of claim 1, wherein the bonder is applied independently of the array of solder balls using software to control placement distance of the bonder with respect to the array of solder balls.

6. The apparatus of claim 1, wherein the IC device comprises at least one of a microprocessor, a microcontroller, a graphics processor, a digital signal processor (DSP), a complex instruction set computing (CISC) processor, a reduced instruction set computing (RISC) processor, and a very long instruction word (VLIW) processor.

7. The apparatus of claim 1, further comprising at least one of a personal computer, a mainframe computer, a handheld device, a portable computer, a set-top box, an intelligent appliance, a workstation, and a server.

8. A system, comprising:
a storage medium;
a bus coupled with the storage medium;
a ball grid array (BGA) package coupled with the bus, the BGA package having a first surface and a second surface and an array of solder balls to align the first surface with the second surface, the first surface coupled with an integrated circuit (IC) device and the second surface coupled with a printed circuit board (PCB); and
a bonder applied between the first surface and the second surface independently of the array of solder balls.

9. The system of claim 8, wherein the bonder comprises a thermoplastic bonder, the thermoplastic bonder is applied using a hot melting jig or a dispenser, the hot melting jig and the dispenser comprise at least one of a hot melt hand applicator, and an adhesive unit.

10. The system of claim 8, wherein the bonder comprises a silicon bonder, the silicon bonder is applied using an epoxy dispenser machine with silicon volume.

11. The system of claim 8, wherein the bonder is applied independently of the array of solder balls using software to control placement distance of the bonder with respect to the array of solder balls.
